(19) United States
(12) Patent Application Publication
(10) Pub. No.: US 2012/0161326 A1
(43) Pub. Date: Jun. 28, 2012

(54) COMPOSITION FOR FILLING THROUGH SILICON VIA (TSV), TSV FILLING METHOD AND SUBSTRATE INCLUDING TSV PLUG FORMED OF THE COMPOSITION

(75) Inventors: Kwang-Seong Choi, Daejeon (KR); Yong Sung Eom, Daejeon (KR); Hyun-cheol Bae, Daejeon (KR); Jong Tae Moon, Daejeon (KR)

(73) Assignee: ELECTRONICS AND TELECOMMUNICATIONS RESEARCH INSTITUTE, Daejeon (KR)

(21) Appl. No.: 13/330,719

(22) Filed: Dec. 20, 2011

(30) Foreign Application Priority Data
Dec. 23, 2010 (KR) 10-2010-0133657

(51) Int. Cl. H01L 23/48; H01L 21/768

(52) U.S. Cl. 257/772; 438/667; 257/E21.586; 257/E23.011

(57) ABSTRACT

Provided is a composition for filling a Through Silicon Via (TSV) including: a metal powder; a solder powder; a curable resin; a reducing agent; and a curing agent. A TSV filling method using the composition and a substrate including a TSV plug formed of the composition are also provided.

### CROSS-REFERENCE TO RELATED PATENT APPLICATION

This application claims priority from Korean Patent Application No. 10-2010-0133657, filed on Dec. 23, 2010, in the Korean Intellectual Property Office, the disclosure of which is incorporated herein in its entirety by reference.

### BACKGROUND OF THE INVENTION

1. Field of the Invention

The present invention relates to a composition for filling a Through Silicon Via (TSV) formed in a wafer of a silicon chip or a silicon interposer in the manufacture of a silicon interposer-based 2.5D-stacked module or a 3D-stacked silicon module, a TSV filling method using the composition, and a substrate including a TSV plug formed of the composition.

2. Description of the Related Art

With the dawn of the ubiquitous and mobile era, there is an increasing need for multimedia terminals providing various services to consumers. To address this need, much attention has been paid to fusion technologies creating new services through the integration of different functions.

As potential realization strategies for fusion technologies, System-in-Package (SiP) and System-on-Package (SoP) technologies have come into spotlight because even though devices or components constituting a system are different from each other in terms of materials or manufacturing processes, the devices or the components can be integrated into one package or module, and thus, it is possible to realize performance improvements, lightness, miniaturization, and cost-savings.

Among the SiP technologies, much attention has been paid to 3D stacking technologies using Through Silicon Via (TSV) techniques capable of reducing electrical parasitic effects due to short interconnections and realizing a more efficient 3D chip layout over a traditional 2D chip layout. Furthermore, taking into consideration that despite the advancement of the semiconductor industry due to downscaling according to Moore's Law, there is a limitation on the downscaling of a transistor gate length to sub-20 nm, it is expected that TSV-based 3D stacking can continuously improve chip integration. In addition, the TSV techniques enable 3D packaging of digitals such as memories, CPUs or base bands, RF/ananlogs, electric power devices, LEDs, chips (e.g., biochips) different in terms of processes and/or materials. Due to the above-described advantages, the TSV techniques have been applied in the manufacture of CMOS image sensor modules, large-capacity memory modules, integrated CPU-memory modules, high-brightness LED (HB LED) modules, etc.

In spite of these advantages, the TSV techniques should satisfy various technical requirements for commercial success, e.g., in terms of a TSV forming technique enabling a high aspect ratio, a technique of forming a dielectric layer/seed layer with a uniform thickness, a TSV filling technique, a thin film wafer handling technique, a microbump formation technique, a 3D stacking technique, a test technique, etc.

Among them, the TSV filling technique is the most important factor in manufacturing low-cost TSV structures. A conventional TSV filling technique is copper electroplating that is applied after forming semiconductor devices or applied to silicon interposers. A conventional TSV filling process using copper electroplating is illustrated in FIG. 1.

Referring to FIG. 1, a dielectric layer 2, a barrier layer 3 and a seed layer 4 are formed in a TSV formed in a silicon wafer 1. The TSV may be formed by Reactive Ion Etching (RIE) or laser drilling. Then, the seed layer 4 is subjected to copper electroplating to fill the TSV with copper 5. Although not shown, subsequent back-grinding, chemical-mechanical polishing (CMP), thin film formation, packaging processes, etc. may be performed to form 3D- or 2.5D-stacked modules.

However, the above-described copper electroplating process requires high-priced exclusive equipment and a special plating solution and is not commonly available because it has been protected by patent rights. Also, 10 hours or more is needed for filling TSVs with a diameter of 50 μm and a depth of 70 μm, thereby incurring a significant increase in process costs. Actually, costs for TSV filling using copper electroplating are 30% or more of the entire TSV process costs. Furthermore, uniform TSV filling over the entire surface of a wafer is difficult, unwanted voids may be easily formed in TSVs, and a currently available void measurement technique such as 3D X-ray is quite time consuming and has low accuracy. In addition, as for TSVs with a dimension greater than a predetermined value, thin film patterns over the TSVs may be broken due to a difference in thermal expansion coefficient between copper and silicon.

In view of the above problems, a TSV filling process using molten solder has been reported. However, handling of a solder solution is difficult, thermal shock to a wafer may occur due to the high melting point of the solder, and, like the copper electroplating, there may be a significant difference in thermal expansion coefficient between the solder and silicon.

A TSV filling technique using resin instead of a metal has been proposed and has already been applied in the field of CMOS image sensors. However, this technique has a problem in application to high-density TSV modules such as silicon interposers and memory packages.

Meanwhile, before forming semiconductor devices or BEOLs (Back End Of Lines), TSVs may be formed to have a small diameter and filled with polysilicon (poly-Si) or tungsten. Even though this technique can increase a routing density due to the small-sized TSVs, poly-Si has high resistance and tungsten has a high internal stress, thus making the deposition of 1 μm or more difficult and causing many problems to the subsequent back-grinding and CMP processes.

### SUMMARY OF THE INVENTION

The present invention provides a composition for filling a Through Silicon Via (TSV).

The present invention also provides a TSV filling method using the composition.

The present invention also provides a substrate including a TSV plug formed of the composition.

According to an aspect of the present invention, there is provided a composition for filling a TSV, including: a metal powder; a solder powder; a curable resin; a reducing agent; and a curing agent.

According to another aspect of the present invention, there is provided a TSV filling method including: applying the above-described composition to a surface of a substrate therein including a TSV and inserting the composition into the TSV; and heating the substrate at the melting point of the solder powder or higher.

According to still another aspect of the present invention, there is provided a substrate including a TSV plug formed of the above-described composition.

According to the inventive TSV filling composition, the solder powder forms intermetallic compounds with the metal powder and a seed layer of a TSV, thereby ensuring reduced resistance and increased mechanical strength. A cured resin occupies spaces that have not been filled with the metal powder and the intermetallic compounds, and thus, it is possible to compensate variations due to the stress or thermal expansion coefficient of the metal used and to provide toughness to the intermetallic compounds, thereby improving brittleness, impact resistance, moisture resistance, etc. Furthermore, the inventive TSV filling method using the above composition can be applied regardless of the shapes of TSVs, and unlike the conventional copper electroplating, it can employ a commonly available process such as screen printing or metal mask printing, thereby leading to a significant reduction in process time and costs. In addition, the inventive TSV filling method can effectively affect the subsequent processes so as to manufacture stable and reliable 3D-stacked silicon modules or silicon interposer-based 2.5D-stacked modules.

### BRIEF DESCRIPTION OF THE DRAWINGS

The above and other features and advantages of the present invention will become more apparent by describing in detail exemplary embodiments thereof with reference to the attached drawings in which:

FIG. 1 is sectional views illustrating a method of filling a TSV of a silicon wafer with copper according to a conventional copper electroplating process.

FIG. 2 is a sectional view illustrating a silicon wafer including a TSV filled with a TSV filling composition according to an embodiment of the present invention.

FIG. 3 is a Scanning Electron Microscopic (SEM) image showing a flake copper powder according to an embodiment of the present invention.

FIG. 4 is a SEM image showing a solder powder according to an embodiment of the present invention.

FIG. 5 is a diagram illustrating a method of filling a TSV with a TSV filling composition according to an embodiment of the present invention using a screen printing process.

FIG. 6 shows a Differential Scanning calorimetry (DSC) analysis result for a TSV filling composition prepared in Example 1.

FIG. 7 shows SEM images and Energy Dispersive Spectroscopy (EDS) analysis results for the TSV filling composition prepared in Example 1 after first DSC analysis.

FIG. 8 shows a change in resistance of TSV filling compositions prepared in Example 2 depending on the amounts of copper powder and solder powder.

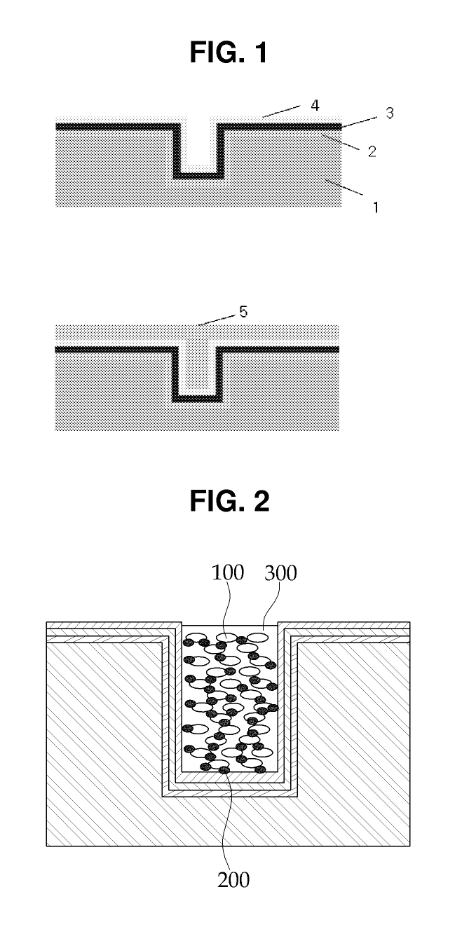

### DETAILED DESCRIPTION OF THE INVENTION

Hereinafter, the present invention will be described in more detail with reference to the accompanying drawings.

A Through Silicon Via (TSV) filling composition according to the present invention includes a metal powder, a solder powder, a curable resin, a reducing agent and a curing agent.

FIG. 2 illustrates the filling of a TSV formed in a silicon wafer with a TSV filling composition according to an embodiment of the present invention. Referring to FIG. 2, a TSV includes a metal powder 100, a solder powder 200, and a cured resin 300.

The metal powder included in the inventive composition serves as an electron pathway and a mechanical support and ensures mechanical strength and toughness required for a TSV. The metal powder may be selected from metal materials having a melting point of 500° C. or higher and capable of forming an intermetallic compound with the solder powder. For example, the metal powder may be selected from copper, nickel, gold, silver, a combination thereof, etc.

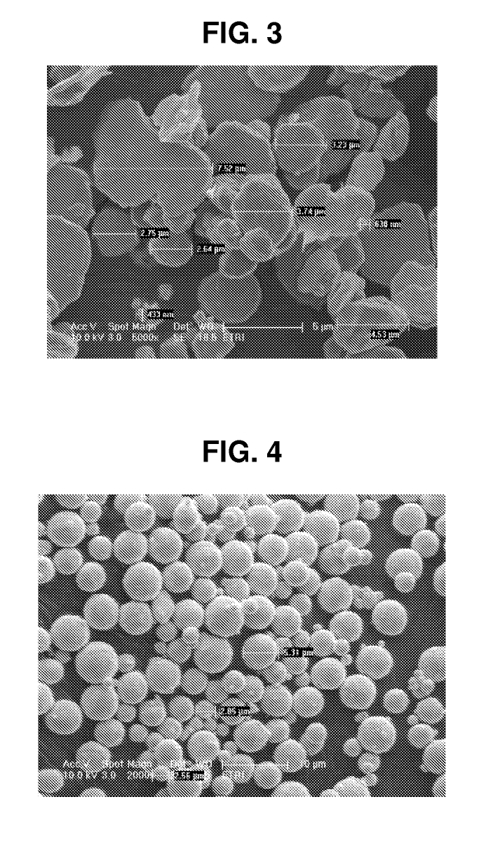

The metal powder may be in the shape of a flake, a sphere, a protruded sphere, etc. For example, a Scanning Electron Microscopic (SEM) image for flake copper powder is shown in FIG. 3. The shape of the metal powder may affect a reaction between the metal powder and the solder powder and the viscosity of the composition, and thus, it is preferable to select a metal powder with an appropriate shape. An average particle diameter of the metal powder may be ⅕ or less of the diameter of a TSV.

The metal powder may be used in an amount of 1 to 50 volume % based on the total volume of the TSV filling composition. When the content of the metal powder satisfies the above range, it is possible to accomplish a desired process viscosity and good electrical conductivity.

The solder powder included in the inventive composition serves as an electric pathway through formation of an intermetallic compound with the metal powder and as a mechanical strength and toughness enhancer due to its high adhesion. The solder powder can also form an intermetallic compound with a metal of a seed layer to thereby enable interconnections between the seed layer and the metal powder and between the metal powders, thus ensuring decreased resistance and increased mechanical strength. In addition, a TSV filling process is performed at a temperature equal to or greater than the melting point of the solder powder, and thus, it is possible to ensure low viscosity required for the filling process. After the TSV filling process, the solder powder is not left but wholly converted to an intermetallic compound or only unreacted metal with a high melting point is left. Thus, even in subsequent high-temperature processes to the TSV filling process, the materials filled in TSVs do not undergo a phase-change, thereby ensuring device reliability.

The solder powder may be a material including at least one of tin (Sn) and indium (In) capable of forming intermetallic compounds with the metal powder and the seed layer. For example, the solder powder may be selected from Sn; In; Sn- or In-containing alloys with an eutectic point such as SnBi, SnAgCu, SnAg, AuSln or InSn; and combinations thereof.

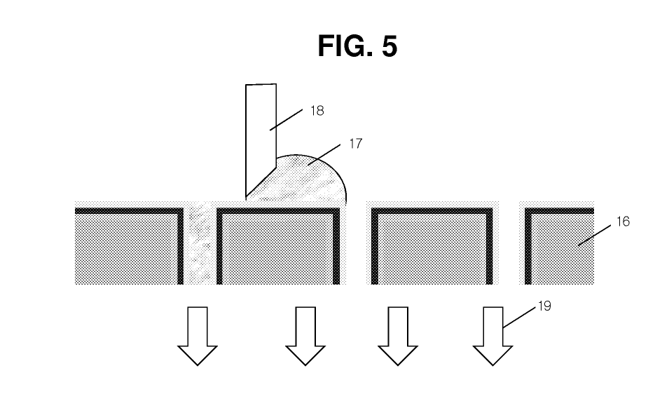

The solder powder may also be in the shape of a flake, a sphere, a protruded sphere, etc. The particle distribution of the solder powder is as defined in IPC standard, J-STD-005 “Requirements for Soldering Paste”. The average particle diameter of the solder powder may affect the reducing power and amount of the reducing agent, and thus, it is important to appropriately select the average particle diameter of the solder powder considering the relationship between the solder powder and the reducing agent. Generally, the average particle diameter of the solder powder may be ⅕ or less of the diameter of a TSV. FIG. 4 is a SEM image showing a spherical solder powder according to an embodiment of the present invention.

The solder powder may be used in an amount of 1 to 50 volume % based on the total volume of the TSV filling composition. When the content of the solder powder satisfies the above range, it is possible to accomplish a desired process viscosity and good electrical conductivity.

The curable resin included in the inventive composition is the most important factor in carrying the metal powder, the solder powder, the reducing agent, the curing agent, etc. and in determining the viscosity of the composition. The viscosity of the curable resin decreases with an increase in temperature. The curable resin is cured in the presence of the curing agent, and a cured resin can fill TSV spaces defined by the metal powder, intermetallic compounds, and a residual solder metal with a high melting point and can compensate variations due to the stress or thermal expansion coefficient of the metal used. In particular, a general intermetallic compound is easily broken by any impact due to high brittleness, but the inventive intermetallic compounds can have high toughness due to the cured resin, thereby ensuring improved mechanical and electrical reliability. In addition, in a reliability test for moisture resistance, the curable resin is responsible for preventing the penetration of moisture into metal or intermetallic compounds.

The curable resin may be selected from epoxy resins commonly known in the art, e.g., bisphenol A-type epoxy resins (e.g.: DGEBA), 4-functional epoxy resins (TGDDM), 3-functional epoxy resins (TriDDM), isocyanate epoxy resins, bismaleimide epoxy resins, etc. but is not limited thereto. In particular, it is preferable to use a halogen-free curable resin in view of the current trend in developing eco-friendly technology. If the curable resin contains a halogen, the halogen may accelerate electro-migration, thereby causing defects such as short-circuit.

The curable resin may be used in an amount of 50 to 95 volume % based on the total volume of the TSV filling composition. When the content of the curable resin satisfies the above range, it is possible to accomplish a desired process viscosity and good electrical conductivity.

The reducing agent included in the inventive composition serves to remove an oxidation film that may be present on the metal powder, the solder powder and the seed layer to thereby efficiently form intermetallic compounds through the reaction of the solder powder with the metal powder and the seed layer.

Examples of the reducing agent include, but are not limited to, carboxyl group (COON)-containing acids such as glutaric acid, malic acid, azelaic acid, abietic acid, adipic acid, ascorbic acid, acrylic acid, and citric acid. The amount of the reducing agent may range from 0.5 to 20 phr (part per hundred part of the curable resin). When the content of the reducing agent satisfies the above range, it is possible to minimize a bubbling phenomenon during the formation of intermetallic compounds.

The curing agent included in the inventive composition serves to cure the curable resin through its reaction with the resin. Examples of the curing agent include, but are limited to, amine-based curing agents such as MPDA (meda phenylen deamin), DDM (dephenyl deamino metane) and DDS (dephenyl deaminozl); anhydride-based curing agents such as MNA (methyl nadic anhydride), DDSA (dodecenyl succinic anhydride), MA (maleic anhydride), SA (succinic anhydride), MTHPA (methyltetrahydrophthalic anhydride), HHPA (hexahydrophthalic anhydride), THPA (tetrahydrophthalic anhydride), PMDA (pyromellitic anhydride); etc. The amount of the curing agent may range from 0.4 to 1.2 Eq (equivalent) with respect to the curable resin. When the content of the curing agent satisfies the above range, it is possible to minimize a bubbling phenomenon during the reaction of the curing agent with the curable resin.

The curable resin, the reducing agent and the curing agent may be separately added to the metal powder and the solder powder. Alternatively, they may be previously mixed and then added in the form of a mixture to the metal powder and the solder powder.

In addition, the inventive composition may further include silica, ceramic powder, etc. with a low thermal expansion coefficient.

The term “Through Silicon Via (TSV)” as used herein is generally also called “through silicon hole”, “silicon through via”, “silicon through hole”, etc. Although the term “TSV” comprehends the word “silicon”, the present invention is not limited to a silicon substrate but may be applied to substrates made of any materials. The term “TSV” may be a blind via with one closed end as well as a through via. There are no particular limitations to the shape and size of the TSV. FIG. 2 illustrates a rectangle-sectional TSV, but the term “TSV” used herein may also have a wedge (V)-shaped section, etc.

The present invention also provides a substrate therein including a TSV, wherein the TSV includes a plug (filling) formed of the above-described composition.

The substrate may be a silicon (Si) wafer, a glass substrate, a printed circuit board (PCB), etc. The TSV plug may be formed by applying the above composition to a surface of the substrate therein including the TSV to insert the composition into the TSV and heating the substrate at the melting point of the solder powder or higher.

The inventive composition may be inserted into the TSV using a simple process commonly known in the art, e.g., a screen printing process or a metal mask printing process. FIG. 5 illustrates a method of filling TSVs formed in a silicon wafer with the inventive composition using a screen printing process. Referring to FIG. 5, a TSV is formed to pass through a silicon wafer 16, and a dielectric layer, a barrier layer and a seed layer are sequentially formed in the TSV. Here, the dielectric layer, the barrier layer and the seed layer may be formed by a method commonly known in the art and do not limit the scope of the present invention. A region below the silicon wafer 16 is in a state of a lower air pressure than its surroundings or a vacuum (see 19 of FIG. 5). First, a TSV filling composition 17 according to an embodiment of the present invention is coated to a predetermined thickness on the silicon wafer 16. Then, the inventive composition 17 is inserted into the TSV using a blade 18 by an air pressure difference between the TSV and its outside. At this time, the silicon wafer 16 may be set to room temperature or if necessary, to the melting point of the solder powder included in the composition or higher.

Instead of using a screen printing process or a metal mask printing process, there may also be used a method including: coating a composition according to an embodiment of the present invention to a predetermined thickness on the entire surface of a silicon wafer and instantly applying a vacuum to the silicon wafer so that all TSVs are filled with the composition. At this time, the silicon wafer may be set to room temperature or if necessary, to the melting point of the solder powder included in the composition or higher.

As described above, when TSV filling is performed at a lower air pressure than its surroundings or in a vacuum state, TSVs are uniformly filled with the composition and bubbles formed in the composition can be effectively removed.

When using a blind via with one closed end, TSV filling may be performed in a vacuum oven by coating the inventive composition on a wafer and lowering the degree of vacuum (i.e., pressurization) so as to insert the composition into TSVs.

After inserting the inventive composition into TSVs according to the above-described method, a substrate is heated at the melting point of the solder powder or higher. The heating may be performed for a sufficient time required for wholly converting the solder powder to intermetallic compounds through its reaction with the metal powder and the seed layer, generally for 30 seconds to 300 minutes. As a result, the solder powder is wholly transformed to intermetallic compounds through its reaction with the metal powder and the seed layer, whereby in the subsequent processes, the melting of the solder does not occur.

The resultant TSV plug may include an intermetallic compound formed through the reaction between the metal powder and the solder powder, an intermetallic compound formed through the reaction between a seed layer of a TSV and the solder powder, a porous matrix formed by the intermetallic compounds and the residual metal powder, and a cured resin filled in pores defined by the matrix.

Subsequently, the resultant substrate may be subjected to cooling to room temperature, back-grinding, CMP, thin film process, etc. to thereby manufacture 3D-stacked semiconductor chips or silicon interposers for 2.5D-stacked modules. Thus-manufactured semiconductor chips and silicon interposers can exhibit improved efficiencies in terms of electrical properties, reliability, etc.

Hereinafter, the present invention will be described more specifically with reference to the following working examples. However, the following working examples are only for illustrative purposes and are not intended to limit the scope of the invention.

### EXAMPLE 1

Preparation of TSV Filling Composition According to an Embodiment of the Present Invention

According to an embodiment of the present invention, a TSV filling composition including copper powder as a metal powder, SnBi powder as a solder powder, DGEBA as a curable resin, maleic acid as a reducing agent and DDS as a curing agent was prepared.

In detail, flake copper (Cu) powder with an average diameter of 5 μm (20 volume %) and the solder powder (10 volume %) were mixed with the curable resin (70 volume %), the reducing agent (20 phr (part per hundred part of the curable resin)) and the curing agent (0.8 Eq with respect to the epoxy resin), and the mixture was uniformly dispersed to prepare a TSV filling composition.

### EXAMPLE 2

Preparation of TSV Filling Compositions According to Another Embodiments of the Present Invention

TSV filling compositions were prepared in the same manner as in Example 1 except for using 15-25 volume % of the metal powder and 15-30 volume % of the solder powder.

### EXPERIMENTAL EXAMPLE 1

Thermal Analysis and Element Analysis for the TSV Filling Composition of Example 1

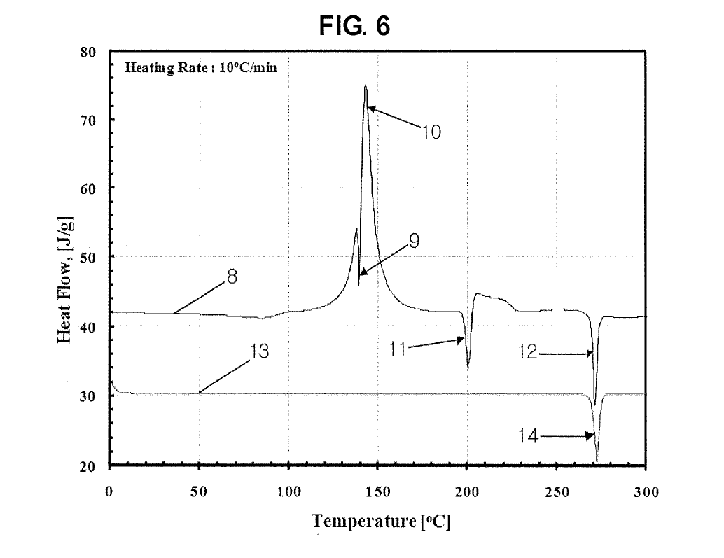

Differential Scanning calorimetry (DSC) analysis for the TSV filling composition prepared in Example 1 was performed, and the result is shown in FIG. 6.

Referring to FIG. 6, with respect to a first DSC curve 8, exothermic reaction occurred at a temperature lower than 140° C. which is the melting point of the SnBi solder. The exothermic reaction was a chemical reaction that occurred on the resin, and its energy was too small to affect the physical properties of the resin. Endothermic reaction 9 that occurred at 140° C. was caused by the melting of the

SnBi solder. The subsequent significant exothermic reaction 10 was probably caused by the reaction between the copper and the solder. Endothermic reaction 11 that occurred at about 200° C. was probably caused by the melting of Sn. Then, endothermic reaction 12 that occurred at about 270° C. was caused by the melting of Bi. With respect to a second DSC curve 13, unlike the first DSC curve, the chemical reaction of the resin, the reaction between the metal and the solder and the melting of the solder did not occur but only the melting of Bi was observed (see 14 of FIG. 6). This means that the resin was completely cured and the solder was wholly converted to intermetallic compounds. Since the conversion rate of the solder to the intermetallic compounds increases with a higher temperature than the melting point of the solder, the solder with a relatively low melting point is wholly converted to intermetallic compounds with a relatively high melting point. Bi maintained its phase since it did not participate in the formation of intermetallic compounds. Bi was molten at its melting point. The above results show that a low temperature process of the melting point of a solder (in this case, the melting point (140° C.) of SnBi) or higher enables TSV filling, and a reducing agent and a curing agent enable the removal of an oxidation film on a metal powder and a solder powder to thereby facilitate the formation of an intermetallic compound between the metal powder and the solder powder and the curing reaction of a resin. If the subsequent processes are performed at less than 270° C., a TSV filling composition does not undergo a phase-change, thus ensuring mechanical and electrical stabilities.

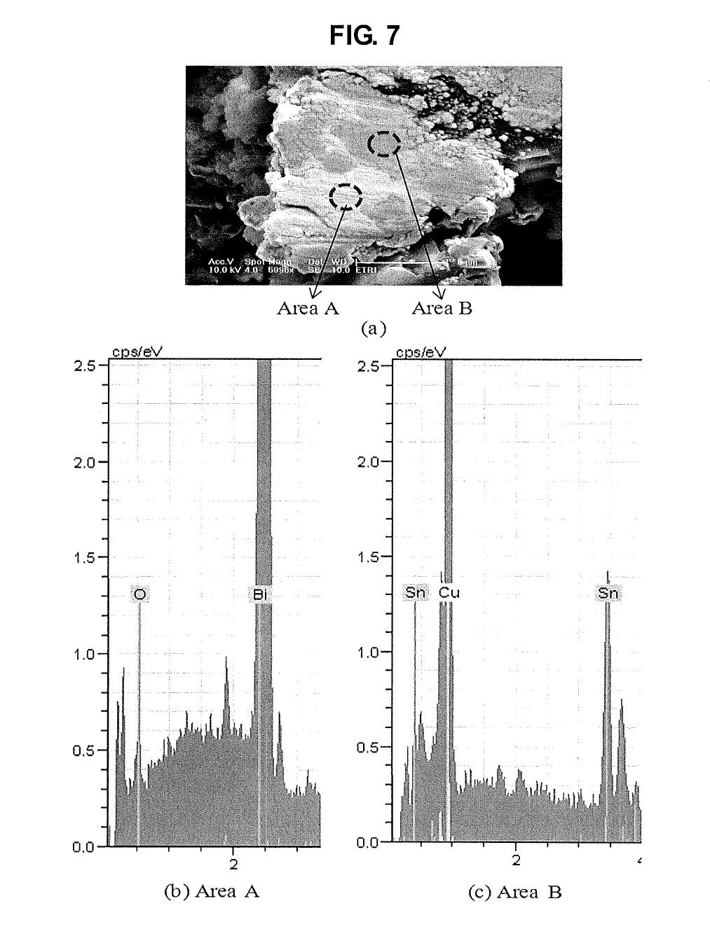

FIG. 7 shows SEM images and Energy Dispersive Spectroscopy (EDS) analysis results for the TSV filling composition prepared in Example 1 after the first DSC analysis. Referring to FIG. 7, Bi is observed in the A area, and Sn and Cu are observed in the B area. This means that Bi maintains its original phase since it does not participate in the formation of an intermetallic compound and Sn forms an intermetallic compound with copper, as described above. Bi, which did not participate in the formation of an intermetallic compound, was molten at 270° C., according to the second DSC analysis (see 14 of FIG. 6).

### EXPERIMENTAL EXAMPLE 2

>Measurement of Resistances for the TSV Filling Compositions of Example 2

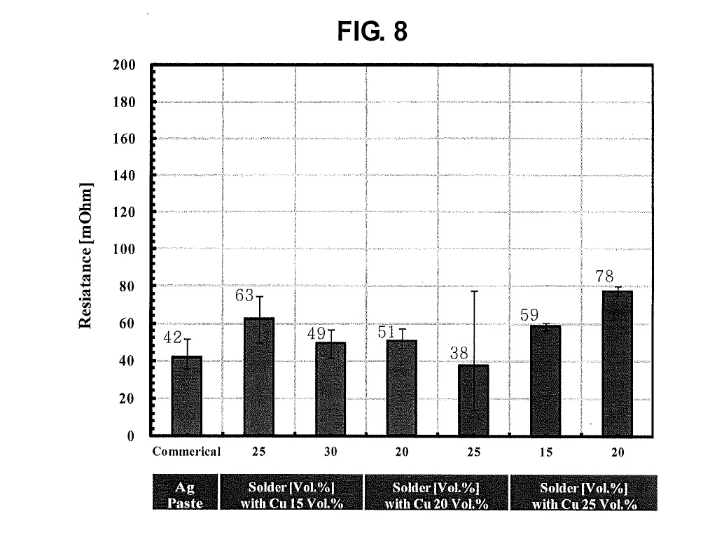

In this experiment, the resistances for the TSV filling compositions prepared in Example 2 were measured. In detail, PCBs wherein four copper pads with a 0.5 mm diameter were exposed in a pitch of 0.93 mm and copper lines were covered with a solder mask were prepared. Adjacent ones of the copper pads were connected to each other by means of each TSV filling composition prepared in Example 2 using a screen printing process and then cured at 180° C. for five minutes and then at 140° C. for 20 minutes. The resistances of the compositions were measured using a 4-point probe method, and the results are shown in FIG. 8.

Referring to FIG. 8, the inventive TSV filling compositions exhibited low resistances comparable with commercially available Ag paste. This result shows that the inventive TSV filling composition can exhibit good electrical properties due to good electrical interconnections of copper, an intermetallic compound and copper, which are repeated in series.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A composition for filling a Through Silicon Via (TSV), the composition comprising: a metal powder; a solder powder; a curable resin; a reducing agent; and
a curing agent.

2. The composition of claim 1, wherein the metal powder is a metal material having a melting point of 500° C. or higher and capable of forming an intermetallic compound with the solder powder.

3. The composition of claim 1, wherein the metal powder is at least one material selected from the group consisting of copper, nickel, gold and silver.

4. The composition of claim 1, wherein the solder powder is a material comprising at least one of tin (Sn) and indium (In).

5. The composition of claim 1, wherein the solder powder is at least one selected from the group consisting of Sn, In, SnBi, SnAgCu, SnAg, AuSln and InSn.

6. The composition of claim 1, wherein the curable resin is an epoxy resin.

7. The composition of claim 1, wherein the reducing agent is a carboxyl group (COON)-containing acid.

8. The composition of claim 1, wherein the curing agent is at least one selected from the group consisting of amine-based curing agents and anhydride-based curing agents.

9. The composition of claim 1, wherein the metal powder is used in an amount of 1 to 50 volume %, the solder powder in an amount of 1 to 50 volume % and the curable resin in an amount of 50 to 95 volume % based on the total volume of the composition, the reducing agent is used in an amount of 0.5 to 20 phr with respect to the curable resin, and the curing agent is used in an amount of 0.4 to 1.2 Eq with respect to the curable resin.

10. The composition of claim 1, further comprising at least one selected from the group consisting of silica and ceramic powder.

11. A TSV filling method comprising:
applying the composition of claim 1 to a surface of a substrate therein comprising a TSV and inserting the composition into the TSV; and
heating the substrate at the melting point of the solder powder or higher.

12. The TSV filling method of claim 11, wherein in the application of the composition to the surface of the substrate and the insertion of the composition into the TSV, the composition is applied to the surface of the substrate at room temperature or the melting point of the solder powder or higher using a screen printing process, a metal mask printing process or a coating process and then inserted into the TSV while changing the internal pressure of the TSV.

13. The TSV filling method of claim 11, wherein the TSV is a through via or a blind via.

14. A substrate comprising a TSV plug formed of the composition of claim 1.

15. The substrate of claim 14, wherein the TSV plug comprises an intermetallic compound formed through the reaction between the metal powder and the solder powder of the composition, an intermetallic compound formed through the reaction between a seed layer of a TSV and the solder powder, a porous matrix formed by the intermetallic compounds and the residual metal powder, and a cured resin filled in pores defined by the porous matrix.

16. The substrate of claim 14, wherein the substrate is a silicon wafer, a glass substrate or a printed circuit board (PCB).

17. The substrate of claim 14, wherein the substrate is a wafer for a 3D-stacked silicon chip or a silicon interposer.
